(19) United States
(12) Patent Application Publication
(10) Pub. No.: US 2026/0113849 A1
(43) Pub. Date: Apr. 23, 2026

(54) ELECTRONIC DEVICE

(71) Applicant: DENSO CORPORATION, Kariya-city (JP)

(72) Inventor: Kei SANADA, Kariya-city (JP)

(21) Appl. No.: 19/354,055

(22) Filed: Oct. 9, 2025

(30) Foreign Application Priority Data
Oct. 21, 2024 (JP) 2024-185000

(51) Int. Cl. H05K 1/18; H01F 27/24; H01F 27/29; H05K 1/11

(52) U.S. Cl. CPC H05K 1/181; H01F 27/24; H01F 27/29; H05K 1/111; H05K 2201/1003

(57) ABSTRACT

An electronic device includes a substrate, an inductor component and solders. The substrate includes an insulating base and lands on the insulating base. The inductor component includes a core and coils disposed on the core and arranged in a predetermined direction orthogonal to a thickness direction of the substrate. The solders join the coils and the lands. Each coil has an external connection terminal adjacent to the substrate. The external connection terminal includes a mounting portion overlapping with a corresponding land in a plan view, and a non-mounting portion overlapping with the core in the plan view. The substrate includes a support portion disposed to overlap with a part of the non-mounting portion of at least one of the external connection terminals in the plan view. The support portion protrudes toward the inductor component relative to the corresponding land, and supports the inductor component through the non-mounting portion.

### CROSS REFERENCE TO RELATED APPLICATION

The present application claims the benefit of priority from Japanese Patent Application No. 2024-185000 filed on October 21, 2024. The entire disclosures of the above application are incorporated herein by reference.

### TECHNICAL FIELD

The present disclosure relates to an electronic device.

### BACKGROUND

WO2022/145094A1, which corresponds to US 2023/0380068A1, discloses an electronic control unit having a printed board and a quad flat no-lead (QFN)-type semiconductor package. The descriptions of WO2022/145094A1 are incorporated herein by reference as explanations of the technical elements in this specification.

### SUMMARY

According to an aspect of the present disclosure, an electronic device includes a substrate, an inductor component and a plurality of solders. The substrate may include an insulating base, and a plurality of lands disposed on one surface of the insulating base. The inductor component may include a core and a plurality of coils that are disposed on the core and arranged in a predetermined direction orthogonal to a thickness direction of the substrate. The plurality of solders may join the coils and the lands. Each of the plurality of coils may have an external connection terminal disposed adjacent to the substrate relative to a surface of the core facing the substrate. The external connection terminal may include a mounting portion disposed so as to overlap with a corresponding land in a plan view from the thickness direction, and a non-mounting portion that is a portion other than mounting portion and disposed so as to overlap with the core in the plan view. The substrate may include a support portion. The support portion may be disposed so as to overlap with a part of the non-mounting portion of at least one of the external connection terminals in the plan view. The support portion may protrude toward the inductor component relative to the corresponding land, and support the inductor component through the non-mounting portion of the at least one of the external connection terminals.

### BRIEF DESCRIPTION OF DRAWINGS

Objects, features and advantages of the present disclosure will become more apparent from the following detailed description made with reference to the accompanying drawings, and in which:

FIG. 1 is a circuit diagram showing a multiphase power supply to which an electronic device according to a first embodiment is applied;

FIG. 2 is a diagram showing an example of an electronic control unit (ECU) equipped with the multiphase power supply;

FIG. 3 is a diagram showing a plan view of an example of the electronic device;

FIG. 4 is a diagram showing a configuration of FIG. 3 with a coupled inductor illustrated in a transparent manner;

FIG. 5 is a diagram showing a perspective view of the coupled inductor;

FIG. 6 is a diagram showing a plan view of the coupled inductor as seen from a top side;

FIG. 7 is a diagram showing a plan view of the coupled inductor as seen from a bottom side;

FIG. 8 is a diagram showing a perspective view of a core;

FIG. 9 is a diagram showing a perspective view of a coil;

FIG. 10 is a diagram showing a cross-sectional view taken along a line X-X in FIG. 3;

FIG. 11 is a diagram showing a cross-sectional view taken along a line XI-XI in FIG. 3;

FIG. 12 is a diagram showing a reference example;

FIG. 13 is a diagram showing a cross-sectional view taken along a line XIII-XIII in FIG. 12;

FIG. 14 is a diagram showing a cross-sectional view of another reference example;

FIG. 15 is a diagram showing a plan view of an electronic device according to a second embodiment;

FIG. 16 is a diagram showing a cross-sectional view taken along a line XVI-XVI in FIG. 15;

FIG. 17 is a diagram showing a plan view of an electronic device according to a third embodiment;

FIG. 18 is a diagram showing a cross-sectional view taken along a line XVIII-XVIII in FIG. 17;

FIG. 19 is a diagram showing an influence of substrate distortion in a reference example;

FIG. 20 is a diagram showing a plan view of a coupled inductor, as seen from a bottom side, in an electronic device according to a fourth embodiment;

FIG. 21 is a diagram showing a leakage magnetic flux in a reference example in which a support portion is not provided;

FIG. 22 is a diagram showing a cross-sectional view taken along a line XXII-XXII in FIG. 21;

FIG. 23 is a diagram showing a gap of a core, a terminal of a coil, and an arrangement of the support portion;

FIG. 24 is a diagram showing a cross-sectional view taken along a line XXIV-XXIV in FIG. 23;

FIG. 25 is a diagram showing a plan view of a modified example;

FIG. 26 is a diagram showing a plan view of another modified example;

FIG. 27 is a diagram showing a plan view of an electronic device according to a fifth embodiment; and

FIG. 28 is a diagram showing a plan view of a modified example.

### DETAILED DESCRIPTION

In WO2022/145094A1, in order to ensure the thickness of a solder that connects a terminal of the semiconductor package to a corresponding land, the printed board is provided with a protrusion so as to come into contact with a lower surface of a molded resin of the semiconductor package. The protrusion is composed of a land that is electrically separated from the land connected to the terminal, and a resist covering this land.

In an inductor component, such as a coupled inductor, in which multiple coils are arranged in a predetermined direction, the terminals of the coils are positioned on the substrate side relative to the surface of the core facing the substrate. The terminal of the coil includes a mounting portion that is disposed so as to overlap with the land, and a non-mounting portion that is a portion other than the mounting portion. The non-mounting portion is positioned directly below the core. Therefore, in a case where the protrusion disclosed in WO2022/145094A1 is applied, if the protrusion does not come into contact with the facing surface of the core, the non-mounting portion of the terminal comes into contact with the surface of the substrate, which may hinder ventilation and may cause ion migration. From the above perspective, or from other perspectives not mentioned, further improvements are required for electronic devices.

The present disclosure provides an electronic device capable of suppressing the occurrence of ion migration.

According to an aspect of the present disclosure, an electronic device includes a substrate, an inductor component and a plurality of solders. The substrate includes an insulating base, and a plurality of lands disposed on one surface of the insulating base. The inductor component includes a core and a plurality of coils that are disposed on the core and arranged in a predetermined direction orthogonal to a thickness direction of the substrate. The plurality of solders join the coils and the lands. Each of the plurality of coils has an external connection terminal disposed adjacent to the substrate relative to a surface of the core facing the substrate. The external connection terminal includes a mounting portion disposed so as to overlap with a corresponding land in a plan view from the thickness direction, and a non-mounting portion that is a portion other than mounting portion and disposed so as to overlap with the core in the plan view. The substrate includes a support portion. The support portion is disposed so as to overlap with a part of the non-mounting portion of at least one of the external connection terminals in the plan view. The support portion protrudes toward the inductor component relative to the corresponding land, and supports the inductor component through the non-mounting portion of the at least one of the external connection terminals.

According to the electronic device described above, the inductor component can be supported via the non-mounting portion of the eternal connection terminal by means of the support portion that is provided on the substrate so as to protrude toward the inductor component. Since the support portion is disposed so as to overlap with a part of the non-mounting portion, a gap can be secured between the remaining part of the non-mounting portion, which is a part without overlapping with the support portion, and the surface of the substrate. Accordingly, it is possible to suppress the obstruction of ventilation and, consequently, to suppress the occurrence of ion migration.

Hereinafter, multiple embodiments of the present disclosure will be described with reference to the drawings. In the following description, corresponding components in each embodiment are denoted by the same reference numerals, and redundant descriptions may be omitted. When only part of the configuration of each embodiment is described, the configuration of the other preceding embodiments can be applied to other parts of the configuration. Furthermore, in the descriptions of each embodiment, not only the explicitly stated combinations of configurations, but also, unless there is a particular problem with their combination, configurations from multiple embodiments may be partially combined with each other even if such combinations are not explicitly described.

### (First Embodiment)

An electronic device according to the present embodiment is provided with an inductor component including a plurality of coils (inductors), as will be described later. The inductor component is, for example, a coupled inductor. Such an electronic device can be applied to various electronic circuits, such as power supply circuits and high-frequency circuits. The electronic device can be used, for example, in configurations employing a plurality of inductors, for the purpose of reducing size and cost. The following describes an example in which the electronic device is applied to a multi-phase power supply.

### Multi-Phase Power Supply

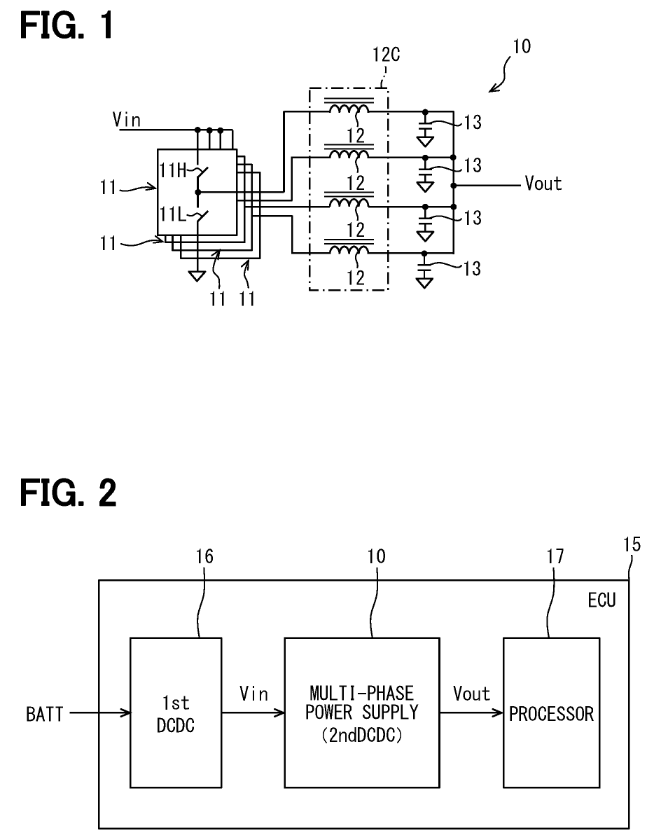

FIG. 1 is a circuit diagram showing an example of a multi-phase power supply to which the electronic device according to the present embodiment is applied. For convenience, some of the drivers are shown in a simplified manner in FIG. 1.

The multi-phase power supply 10 shown in FIG. 1 is a step-down DC-to-DC converter. The multi-phase power supply 10 steps down an input voltage Vin to a predetermined voltage and outputs the stepped-down voltage as an output voltage Vout. The multi-phase power supply 10 includes a plurality of drivers 11, a plurality of inductors 12 provided corresponding to the drivers 11, and capacitors 13. The multi-phase power supply 10 has a plurality of phases. The phases may also be referred to as stages or channels.

Each of the drivers 11 includes switching elements 11H and 11L. The switching elements 11H and 11L are connected in series between a power supply line, to which the input voltage Vin is applied, and a ground (GND) line, with the switching element 11H positioned on a higher potential side. The switching elements 11H and 11L may be, for example, MOSFETs or IGBTs. The switching elements 11H and 11L may also be bipolar transistors. MOSFET is an abbreviation for Metal Oxide Semiconductor Field Effect Transistor. IGBT is an abbreviation for Insulated Gate Bipolar Transistor.

One end of the inductor 12 is connected to a connection point, such as a midpoint, between the switching elements 11H and 11L. The other end of the inductor 12 is connected to an output line. The inductor 12 is provided individually for each driver 11. In each phase, the driver 11 and the inductor 12 are connected in parallel with each other. This parallel connection allows the output current from the multi-phase power supply 10, that is, a load current, to be increased. The number of phases is not particularly limited. The illustrated multi-phase power supply 10 has four phases.

The capacitor 13 is connected to the output line. A positive terminal of the capacitor 13 is connected to the output line. A negative terminal of the capacitor 13 is connected to ground. The capacitor 13 may be provided individually for each phase, or may be provided commonly for a plurality of phases. The illustrated capacitor 13 is provided for each phase. Providing the capacitor 13 for each phase allows the capacitor 13 to be placed closer to the inductor 12, thereby shortening a return path from the capacitor 13. In this case, emissions can be improved.

The multi-phase power supply 10 may be provided with a control unit (not shown). The control unit, for example, performs a voltage mode control based on feedback of the output voltage Vout, thereby controlling the operation of the driver 11, that is, the operations of the switching elements 11H and 11L. The control unit determines the pulse width (duty cycle) of the PWM signal based on the output voltage Vout, and controls the output voltage Vout of the multi-phase power supply 10. The control unit may perform a current mode control, in place of the voltage mode control.

The control unit synchronously controls the plurality of drivers 11 so that the plurality of drivers 11 perform switching operations at mutually different phases. In this way, by using the multiple phases, it is possible to effectively increase the switching frequency, even if the switching frequencies of the plurality of drivers 11 are the same. As a result, it is possible to reduce a ripple component of the output voltage Vout and improve responsiveness. The control unit switches the drivers 11 to be operated in switching mode, that is, the number of drive phases, according to the load current. The control unit compares the load current with a threshold current, and increases and/or decreases the number of drive phases according to the comparison result.

The multi-phase power supply 10 may be configured to include an inductor component in which the plurality of inductors 12 are packaged. The illustrated multi-phase power supply 10 includes a coupled inductor 12C as the inductor component.

FIG. 2 shows an application example of the multi-phase power supply 10. The multi-phase power supply 10 described above is applied, for example, to an ECU 15. ECU is an abbreviation for Electronic Control Unit. The ECU 15 may be mounted, for example, on a mobile object. The mobile object may be, for example, a vehicle, an aircraft, a ship, a construction machine, or an agricultural machine. The mobile object may be a manned mobile object or an unmanned mobile object.

The illustrated ECU 15 is mounted on a vehicle. The ECU 15 may be, for example, an autonomous driving ECU, or an ADAS ECU that executes control to assist the driving operations of the driver. ADAS is an abbreviation for Advanced Driving Assistant System. For example, Levels 3 to 5 as defined by the Society of Automotive Engineers (SAE International) correspond to autonomous driving levels, while Levels 1 and 2 as defined by the SAE International correspond to driving assistance levels. The ECU 15 may also be an infotainment ECU or a cockpit ECU. The cockpit ECU is an ECU that controls devices such as a meter unit, a navigation unit, and an air conditioning unit.

The ECU 15 includes a primary power supply circuit (1st DCDC) 16, the multi-phase power supply 10 as a secondary power supply circuit (2nd DCDC), and a processor 17. The primary power supply circuit 16 is configured to step down an input voltage to a predetermined voltage and output the voltage. The primary power supply circuit 16 is a step-down type DC-to-DC converter. For example, the primary power supply circuit 16 generates a constant voltage (for example, 5V) that is lower than the supply voltage, based on power supplied from a battery (BATT) mounted in the vehicle. The multi-phase power supply 10 uses the voltage generated by the primary power supply circuit 16 as its input voltage Vin. The multi-phase power supply 10 steps down the input voltage Vin to a predetermined voltage (for example, around 1V) and outputs the voltage as the output voltage Vout.

The processor 17 is an example of a load that operates by receiving power supplied from the multi-phase power supply 10. The processor 17 may be, for example, a CPU, GPU, or the like. CPU is an abbreviation for Central Processing Unit. GPU is an abbreviation for Graphics Processing Unit. The ECU 15 may be provided with only one processor 17, or may be provided with a plurality of processors 17. The ECU 15 may be provided with a plurality of types of processors 17. The processor 17 executes a control program stored in a memory (not shown) to perform a predetermined processing for control. The memory is a non-transitory tangible storage medium that non-temporarily stores computer-readable programs, data and the like.

A core voltage of the processor 17 is around 1 V (for example, less than 1 V), and a load current is several tens of amperes or more (for example, 100 A or more). In order to address such a low voltage and a high current, the ECU 15 employs the multi-phase power supply 10 as its power circuit. The multi-phase power supply 10 steps down the input voltage to a voltage corresponding to the core voltage of the processor 17 and outputs the stepped-down voltage. By using the multi-phase power supply 10, it is possible to support the enhanced performance of the processor 17 required for improvements in the autonomous driving levels and the evolution of infotainment functions, and in particular, to support autonomous driving at Level 3 or higher.

In a high-performance processor 17, the current consumption fluctuates rapidly according to computational processing, so a large number of capacitors 13 are required to supply a stable voltage even during sudden changes in load. By using the coupled inductor 12C, magnetic fields between phases are cancelled out, and the effective inductance value can be reduced. Therefore, responsiveness when the load suddenly changes improves. As such, as compared to a general configuration using a single inductor, the number of capacitors 13 can be significantly reduced. For example, the size of the ECU 15 can be reduced.

### Outline Configuration of Electronic Device

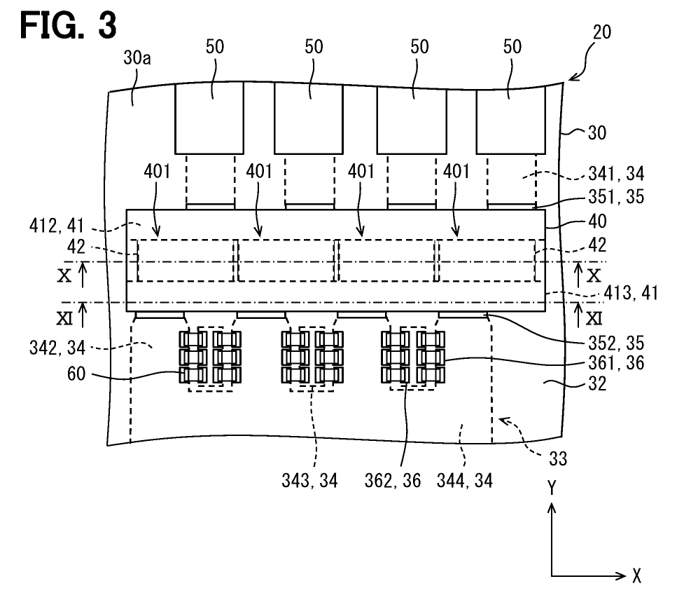

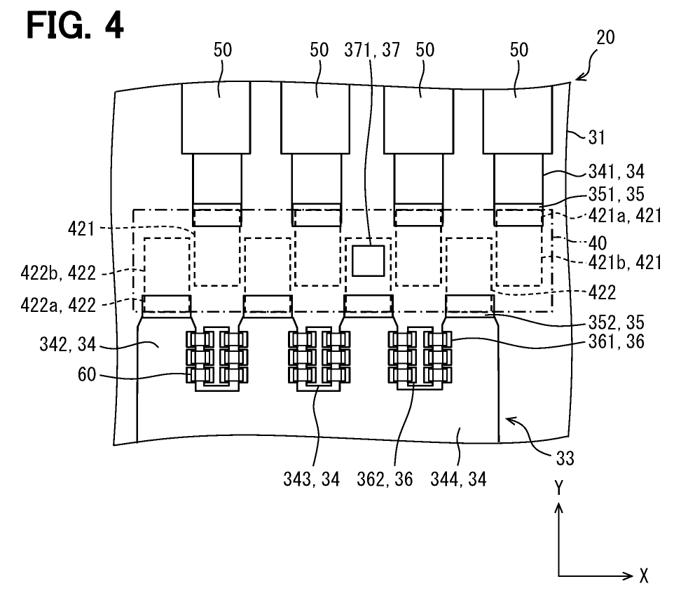

FIG. 3 shows a plan view of an electronic device as an example. FIG. 3 shows an enlarged view of the vicinity of a coupled inductor in the electronic device. In FIG. 3, wirings covered with a resist are indicated by dashed lines. FIG. 4 shows a configuration of FIG. 3 with the coupled inductor illustrated in a transparent manner. In FIG. 4, the resist is omitted for convenience. In FIG. 4, an outline of the coupled inductor is indicated by a one-dot chain line. In addition, terminals of the coupled inductor are indicated by dashed lines.

As shown in FIGS. 3 and 4, an electronic device 20 includes a substrate 30 and a plurality of components mounted on the substrate 30. The plurality of components includes a coupled inductor 40, a switching device 50, and a capacitor 60. The electronic device 20 provides the above-described multi-phase power supply 10. The electronic device 20 may also provide the ECU 15. In such a case, elements of the processor 17 and the primary power supply circuit 16 are also mounted on the substrate 30. The electronic device 20 may further include a housing that accommodates other elements constituting the electronic device 20.

Hereinafter, a thickness direction of the substrate is referred to as a Z direction. A direction orthogonal to the Z direction and corresponding to an arrangement direction of the plurality of coils is referred to as an X direction. A direction orthogonal to both the Z direction and the X direction is referred to as a Y direction. Unless otherwise specified, a shape as viewed from a direction along the Z direction, that is, a shape along an XY plane including the X direction and the Y direction is referred to as a planar shape. A plan view as viewed from the Z direction may be simply referred to as a plan view.

The substrate 30 may also be referred to as a printed circuit board, a printed wiring board, or a wiring substrate. The substrate 30 includes an insulating base 31, a resist 32, and a conductor 33. The insulating base 31 is made of an electrically insulating material such as resin. The resist 32 is a so-called solder resist. The insulating base 31 has opposite surfaces opposite in the Z direction. Of the opposite surfaces of the insulating base 31, the resist 32 covers the surface on which components are soldered. In the illustrated electronic device 20, the coupled inductor 40, the switching device 50, and the capacitor 60 are disposed on a first surface 30a of the substrate 30. The resist 32 is disposed on the insulating base 31 at least on the first surface 30a side.

The conductor 33 is disposed on the insulating base 31. At least a portion of the conductor 33 forms a circuit together with components mounted on the substrate 30. The conductor 33 includes a wiring 34. The wiring 34 is formed, for example, by patterning a metal foil. The wiring 34 is disposed at least on a surface layer of the insulating base 31, on the first surface 30a side. The wiring 34 may be disposed not only on the surface layer on the first surface 30a side, but also on the surface layer on the rear side, i.e., on the second surface side. The wiring 34 may be disposed inside the insulating base 31. The substrate 30 may be a single-sided substrate, a double-sided substrate, or a multilayer substrate including three or more wiring layers. The conductor 33 may include, for example, a via conductor. The via conductor is provided by a conductive material, such as a plating, disposed in a through hole (via) that is formed in the insulating layer constituting the insulating base 31. The via conductor electrically connects the wirings 34 of different layers.

As an example, the substrate 30 is a multilayer substrate. The wiring 34 includes wirings 341, 342, 343, and 344, which are disposed on the surface layer on the first surface 30a side. The wiring 341 electrically connects an inductor 401 (coil 42) and the switching device 50. The wiring 341 is provided for each inductor 401. As an example, the wiring 341 extends in the Y direction. The plurality of wirings 341 are arranged side by side in the X direction.

The wiring 342 electrically connects the inductor 401 (coil 42) and the capacitor 60. The wiring 342 is provided for each inductor 401. As an example, the wiring 342 extends in the Y direction. The plurality of wirings 342 are arranged side by side in the X direction. The wiring 342 is provided at a position separated from the wiring 341 in the Y direction. The coupled inductor 40 is positioned between the wirings 342 and the wirings 341 in the Y direction.

The wiring 343 is a ground wiring. The ground wiring provides a reference potential, which is the ground potential, on the substrate 30. The wiring 343 is electrically connected, for example, to a ground wiring disposed in an inner layer via a via conductor (not shown). The wiring 343 is disposed between the adjacent wirings 342. The wiring 344 and the wiring 343 are alternately arranged in the X direction. The wiring 34 includes three wirings 343.

The wiring 344 electrically connects the inductor 401 and the capacitor 60 to the output terminal of the multi-phase power supply 10. The wiring 344 and the wirings 342 are arranged in the Y direction. The single wiring 344 is connected to the plurality of wirings 342. The wiring 344 is a common wiring for the plurality of wirings 342. The plurality of wirings 342 are connected to the same wiring 344.

The conductor 33 includes lands 35 and 36. The lands 35 and 36 are portions of the wirings 34 that are exposed from the resist 32 to allow solder bonding with components. The lands 35 and 36 are arranged on the surface layer of the insulating base 31 on the first surface 30a side. The lands 35 and 36 provide functions as the wirings. The lands 35 and 36 may each have an over-resist structure in which an outer peripheral edge is covered by the resist 32, or a normal-resist structure in which the outer peripheral edge is not covered by the resist 32.

The land 35 is provided corresponding to the coil 42 of the coupled inductor 40. The land 35 includes lands 351 and 352. The land 351 is disposed at the end of the wiring 341 on the coupled inductor 40 side. The land 352 is disposed at the end of the wiring 342 on the coupled inductor 40 side. The land 351 is provided at a position separated from the land 352 in the Y direction. A terminal 421 of the coil 42 is soldered to the land 351. A terminal 422 of the coil 42 is soldered to the land 352.

As an example, the substrate 30 has eight lands 35 in total. The eight lands 35 include four lands 351 and four lands 352. The four lands 351 are arranged in the X direction. The four lands 352 are arranged in the X direction. The land 351 and the land 352 that are soldered to the same coil 42 are offset from each other in the X direction. The lands 351 and the lands 352 are alternately arranged in the X direction. The land 351 and the land 352 that are adjacent to each other in the X direction are arranged either with a slight gap between them or without any gap between them.

The land 36 is provided corresponding to the capacitor 60. The land 36 includes lands 361 and 362. The land 361 is disposed at an end of the wiring 342 in the X direction. The land 362 is disposed at an end of the wiring 343 in the X direction. The lands 361 and the land 362 are disposed so as to face each other in the X direction. A positive terminal of the capacitor 60 is soldered to the land 361, and a negative terminal of the capacitor 60 is soldered to the land 362. In the illustrated substrate 30, the lands 36 are arranged side by side in the X direction. The substrate 30 has a support portion 37. The support portion 37 will be described later.

The coupled inductor 40 is disposed on the first surface 30a of the substrate 30. The coupled inductor 40 provides the coupled inductor 12C described above. The coupled inductor 40 is an inductor component including a core 41 and a plurality of coils 42. As an example, the coupled inductor 40 includes four coils 42. The plurality of coils 42 are arranged side by side in the X direction. The coupled inductor 40 includes four inductors 401. One end of the coil 42 is soldered to the land 351, and the other end of the coil 42 is soldered to the land 352. Details of the structure of the coupled inductor 40 will be described later.

The switching device 50 provides the driver 11 described above, that is, the switching elements 11H and 11L. The switching device 50 is provided corresponding to the coil 42, that is, the inductor 401. The illustrated switching device 50 constitutes the switching elements 11H and 11L for one phase. One switching device 50 constitutes the driver 11 for one phase. The switching device 50 may be a semiconductor package including a plurality of semiconductor elements. Alternatively, the switching device 50 may be provided for each of the switching elements 11H and 11L. The plurality of switching devices 50 are arranged in the X direction. The switching devices 50 and the coupled inductor 40 are arranged in the Y direction. The switching device 50 is soldered to a land (not shown) provided at the end of the wiring 341 on the switching device 50 side.

The capacitor 60 provides the capacitor 13 described above. The capacitor 60 is, for example, a chip capacitor. In the Y direction, the coupled inductor 40 is disposed between the capacitors 60 and the switching devices 50. The positive terminal of the capacitor 60 is soldered to the land 361, and the negative terminal of the capacitor 60 is soldered to the land 362. In the example, a plurality of capacitors 60 are provided for each inductor 401. The plurality of capacitors 60 are arranged so as to bridge the adjacent wirings 342 and 343. The capacitors 60 corresponding to one inductor 401 are arranged in a row in the Y direction, forming a capacitor row. The capacitors 60 corresponding to one inductor 401 form, for example, a plurality of capacitor rows. The plurality of capacitor rows are arranged in the X direction.

### Coupled Inductor

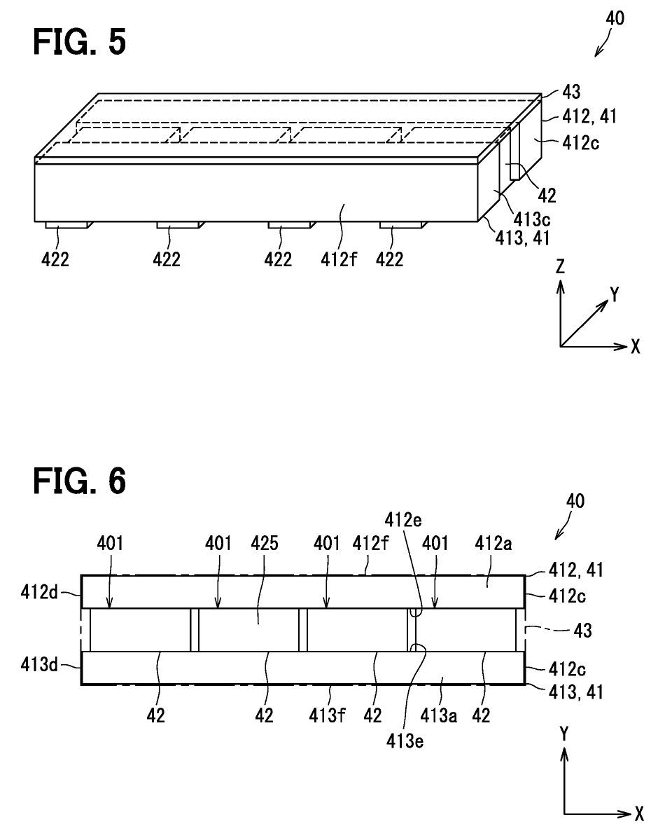

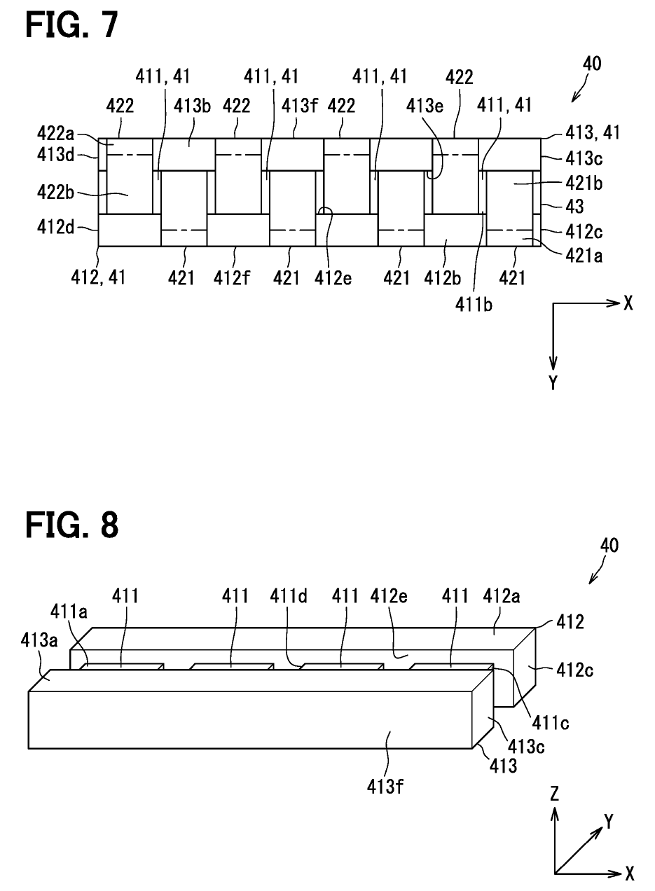

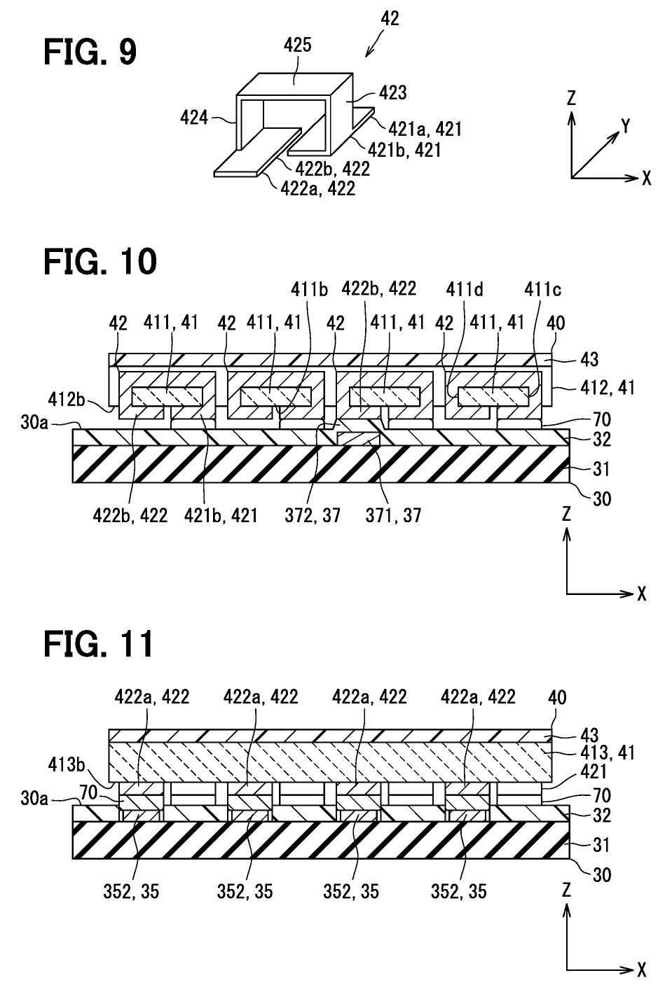

FIG. 5 is a perspective view of the coupled inductor. FIG. 6 is a plan view of the coupled inductor as seen from the top side. FIG. 7 is a plan view of the coupled inductor as seen from the bottom side. In FIG. 7, a one-dot chain line indicates a boundary between a mounting portion and a non-mounting portion. FIG. 8 is a perspective view of a core. FIG. 9 is a perspective view of a coil.

As shown in FIGS. 3 to 9, one coupled inductor 40 provides a plurality of inductors 401. The coupled inductor 40 includes a core 41 and a plurality of coils 42. The plurality of coils 42 are arranged on a single core 41, that is, a common core 41, and are magnetically coupled to each other. By using the coupled inductor 40, the magnetic fluxes between phases can be cancelled out each other, and the effective inductance can be reduced.

The core 41 is made of a magnetic material such as ferrite. The core 41 functions as a magnetic circuit. The core 41 has a plurality of core portions 411 and end portions 412 and 413. The core 41 passes through the coil 42. The core portions 411 are provided individually for the coils 42. The coil 42 is wound around the core portion 411. The core portion 411 extends in the Y direction. The plurality of core portions 411 are arranged in the X direction at predetermined intervals. As an example, the core 41 has four core portions 411. Each core portion 411 is formed into a substantially rectangular parallelepiped shape. The four core portions 411 have the same shape as each other. The end portion 412 corresponds to a first end portion, and the end portion 413 corresponds to a second end portion.

The core portion 411 has an upper surface 411a, a lower surface 411b, and side surfaces 411c and 411d. The lower surface 411b is the surface on the substrate 30 side in the Z direction. The upper surface 411a is the surface opposite to the lower surface 411b in the Z direction. The side surface 411c is the surface opposite to the side surface 411d in the X direction.

The end portion 412 and the end portion 413 are arranged to face each other in the Y direction. The core portions 411 are interposed between the end portion 412 and the end portion 413. The end portion 412 and the end portion 413 extend in the X direction, along which the plurality of core portions 411 are arranged. First ends of the plurality of core portions 411 are connected to the end portion 412, and second ends of the plurality of core portions 411 are connected to the end portion 413. The end portions 412 and 413 magnetically connect the plurality of core portions 411. The illustrated end portions 412 and 413 have the same shape as each other. The end portions 412 and 413 are each formed in a substantially rectangular parallelepiped shape with the X direction as the longitudinal direction.

The end portion 412 has an upper surface 412a, a lower surface 412b, and side surfaces 412c, 412d, 412e, and 412f. The end portion 413 has an upper surface 413a, a lower surface 413b, and side surfaces 413c, 413d, 413e, and 413f. The lower surfaces 412b and 413b are the surfaces on the substrate 30 side in the Z direction. The upper surfaces 412a and 413a are the surfaces opposite to the lower surfaces 412b and 413b in the Z direction. The side surfaces 412c and 413c are the surfaces opposite to the side surfaces 412d and 413d in the X direction. The side surface 412e and the side surface 413e face each other in the Y direction. The side surface 412f is the surface opposite to the side surface 412e in the Y direction, and the side surface 413f is the surface opposite to the side surface 413e in the Y direction.

In the illustrated core 41, the lower surfaces 411b, 412b, and 413b are substantially coplanar. The upper surfaces 412a and 413a are farther from the substrate 30 than the upper surface 411a. The upper surface 411a is closer to the substrate 30 than the upper surfaces 412a and 413a.

The coil 42 is made of a metal material with good electrical conductivity, such as copper. The coil 42 is formed by processing a metal plate material, rather than a metal wire material The metal plate material may also be referred to as a metal frame. The plurality of coils 42 are made of the same material and have the same shape as each other. The plurality of coils 42 have approximately equal inductance to each other. The plurality of coils 42 are arranged in the X-direction at predetermined intervals. The plurality of coils 42 are arranged in the same orientation as each other. The coil 42 is fixed to the core 41, for example, by adhesive.

The coil 42 is formed by bending a metal plate material having a predetermined thickness. The coil 42 has terminals 421 and 422, side walls 423 and 424, and an upper wall 425. The terminals 421 and 422 serve as external connection terminals of the coil 42 and are soldered to corresponding lands 35. The terminal 421 is soldered to the land 351, and the terminal 422 is soldered to the land 352.

The plate thickness directions of the terminals 421 and 422 are approximately parallel to the Z direction. One of the plate surfaces, that is, the lower surface of each of the terminals 421 and 422 faces the first surface 30a of the substrate 30. The terminals 421 and 422 extend in the Y direction. The illustrated terminals 421 and 422 each have a substantially planar rectangular shape with the Y direction as the longitudinal direction. The terminals 421 and 422 are arranged side by side in the X direction with a predetermined spacing. A portion of the side surface of terminal 421 and a portion of the side surface of terminal 422 face each other in the X direction. The terminal 421 extends in the Y direction from the portion facing the terminal 422 toward the side surface 412f, that is, toward the switching device 50. The terminal 422 extends in the Y direction from the portion facing the terminal 421 toward the side surface 413f, that is, toward the capacitor 60. The terminals 421 and 422 are arranged offset in the Y direction so that the non-mounting portions 421b and 422b, which will be described later, face each other at least at part in the X direction.

The terminal 421 has a mounting portion 421a and the non-mounting portion 421b. The mounting portion 421a is a portion that overlaps with the corresponding land 351 in a plan view, that is, in the Z direction. The mounting portion 421a is a portion that is soldered to the land 351. The non-mounting portion 421b is a portion of the terminal 421 excluding the mounting portion 421a. The non-mounting portion 421b is arranged so as to overlap with the core 41 in the plan view. In the plan view, the entirety of the non-mounting portion 421b is positioned directly below the core 41. In the illustrated coil 42, the entirety of the terminal 421 is positioned directly below the core 41 in the plan view. The mounting portion 421a may include a portion positioned directly below the core 41 and a portion positioned outside the core 41.

Similarly, the terminal 422 has a mounting portion 422a and a non-mounting portion 422b. The mounting portion 422a is a portion that overlaps with the corresponding land 352 in a plan view, that is, in the Z direction. The mounting portion 422a is soldered to the land 352. The non-mounting portion 422b is a portion of the terminal 422 excluding the mounting portion 422a. The non-mounting portion 422b is arranged so as to overlap with the core 41 in the plan view. In the plan view, the entirety of the non-mounting portion 422b is positioned directly below the core 41. The non-mounting portion 422b and the non-mounting portion 421b are alternately arranged at a predetermined interval in the X direction. In the illustrated coil 42, the entirety of the terminal 422 is positioned directly below the core 41 in the plan view. The mounting portion 422a may include a portion positioned directly below the core 41 and a portion positioned outside the core 41.

The side wall 423 is connected to the portion of the terminal 421 that faces terminal 422, that is, to the non-mounting portion 421b. The side wall 423 is bent at an angle of approximately 90 degrees with respect to the terminal 421. The plate thickness direction of the side wall 423 is approximately parallel to the X direction. The side wall 423 has a width equal to the length of the portions of the terminals 421 and 422 facing each other, and extends in the Z direction. Similarly, the side wall 424 is connected to the portion of the terminal 422 that faces terminal 421, that is, to the non-mounting portion 422b. The side wall 424 is bent at an angle of approximately 90 degrees with respect to the terminal 422. The plate thickness direction of the side wall 424 is approximately parallel to the X direction. The side wall 424 has a width equal to the length of the portions of the terminals 421 and 422 facing each other, and extends in the Z direction, that is, in the same direction as the side wall 423. The lower end of the side wall 423 is connected to the terminal 421, and the lower end of the side wall 424 is connected to the terminal 422.

The upper wall 425 bridges the side walls 423 and 424. The upper wall 425 extends in the X direction. One end of the upper wall 425 is connected to the upper end of the side wall 423, and the other end of the upper wall 425 is connected to the upper end of the side wall 424. The upper wall 425 has the same width as the side walls 423 and 424. In the plan view, the upper wall 425 covers the side walls 423 and 424 and the portions of the terminals 421 and 422 facing each other in the X direction. The portions of the terminals 421 and 422 facing each other in the X direction may be referred to as the facing portions.

The facing portions of the terminals 421 and 422, the side walls 423 and 424, and the upper wall 425 surround the core portion 411 of the core 41. The facing portions of the terminals 421 and 422, the side walls 423 and 424, and the upper wall 425 are mounted on and wound around the core portion 411. The end portions 412 and 413 of the core 41 are disposed on the portions of the terminals 421 and 422 excluding the facing portions, that is, the extended portions of the terminals 421 and 422. The terminals 421 and 422 include portions that are positioned closer to the substrate 30 than the lower surfaces 411b, 412b, and 413b of the core 41. The lower surfaces of terminals 421 and 422 are located closer to the first surface 30a than the lower surfaces 411b, 412b, and 413b of the core 41.

Between the adjacent coils 42, one side wall 423 of one coil 42 and the other side wall 424 of the other coil 42 face each other. In the illustrated coupled inductor 40, the outer surface of the side wall 423 located at one end of the coupled inductor 40 is offset relative to the side surfaces 412c and 413c so as to be recessed from the side surfaces 412c and 413c in the X direction. Similarly, the outer surface of the side wall 424 located at the other end of the coupled inductor 40 is offset relative to the side surfaces 412d and 413d so as to be recessed from the side surfaces 412d and 413d in the X direction. The upper surface of the upper wall 425 of the coil 42 is offset relative to the upper surfaces 412a and 413a so as to be recessed from the upper surfaces 412a and 413a in the Z direction.

For example, the outer surface of the side wall 423 at the one end may be made substantially flush with the side surfaces 412c and 413c. The outer surface of the side wall 424 at the other end may also be made substantially flush with the side surfaces 412d and 413d. The upper surface of the upper wall 425 may also be made substantially flush with the upper surfaces 412a and 413a.

The coupled inductor 40 may be provided with a cover in addition to the core 41 and the plurality of coils 42. The illustrated coupled inductor 40 is provided with a cover 43. The cover 43 is disposed on the upper surface of the core 41 and covers the core 41 and the plurality of coils 42. The cover 43 is used, for example, for the purpose of restricting foreign matter from adhering to the coupled inductor 40. The cover 43 is used, for example, for the purpose of restricting short circuits between the coils 42 due to, for example, conductive foreign matter. The cover 43 is used, for example, for the purpose of enhancing the suction capability during transport when mounting the coupled inductor 40 onto the substrate 30.

The material of the cover 43 is not particularly limited, as long as it can achieve the purposes described above. For example, the material of the cover 43 may be a resin or a magnetic material. The cover 43 may be made of the same material as the core 41. The cover 43 can function as a part of the core 41. For example, the cover 43 is a resin film or a resin sheet. The cover 43 has a substantially rectangular planar shape with the X direction as its longitudinal direction. The cover 43 is disposed so as to enclose the core 41 and the plurality of coils 42 in the plan view. The cover 43 is adhesively fixed to the upper surfaces 412a and 413a of the end portions 412 and 413.

### Support Portion and Mounting Structure

FIG. 10 is a cross-sectional view taken along a line X-X in FIG. 3. FIG. 10 shows a support structure of the coupled inductor 40 by the support portion. FIG. 11 is a cross-sectional view taken along a line XI-XI in FIG. 3. FIG. 11 shows a mounting structure of the coupled inductor in a state supported by the support portion.

As shown in FIGS. 4 and 10, the substrate 30 has at least one support portion 37. The support portion 37 is provided so as to overlap with a part of the non-mounting portion 421b or 422b of the terminal 421 or 422 in the plan view. The support portion 37 protrudes toward the coupled inductor 40 side relative to the land 35. On the first surface 30a, the support portion 37 protrudes relative to the peripheral area of the support portion 37. The support portion 37 is a protruding section located directly below the non-mounting portion 421b or 422b. The support portion 37 supports the coupled inductor 40 via the non-mounting portion 421b or 422b.

The illustrated electronic device 20 is provided with only one support portion 37. The support portion 37 includes a support conductor 371 and a resist 372. The support conductor 371 is disposed at a position separate from the lands 35, in a surface layer of the insulating base 31 on the first surface 30a side. The resist 372 covers the support conductor 371. The resist 372 is a part of the resist 32. The support conductor 371 is electrically isolated from all of the lands 35 that are joined to the coils 42. The support conductor 371 is a conductor 33 that does not constitute a circuit. In other words, the support conductor 371 is a conductor that does not provide a wiring function. The support conductor 371 has a substantially rectangular shape in a plan view. The support conductor 371 is provided so as to overlap with a part of one non-mounting portion 422b. The support conductor 371 is disposed so as to overlap with the non-mounting portion 422b that is closest to the center in the longitudinal direction (X direction) of the coupled inductor 40. The support conductor 371 is disposed such that the center of the support conductor 371 and the center of the coupled inductor 40 in the short-side direction (Y direction) substantially coincide with each other.

The support portion 37 is in contact with the lower surface of the non-mounting portion 422b of the terminal 422, and supports the coupled inductor 40. As a result, in an area directly below the coupled inductor 40, a gap, which allows ventilation, is secured between the first surface 30a of the substrate 30 and the parts of the non-mounting portions 421b and 422b except for the part supported by the support portion 37. An even larger gap is secured between the lower surfaces 411b, 412b, and 413b of the core 41, which are positioned above the lower surfaces of the terminals 421 and 422, and the first surface 30a of the substrate 30. The parts of the non-mounting portions 421b and 422b, excluding the part supported by the support portion 37, include the non-mounting portions 421b and 422b that are not in contact with the support portion 37 as well as a non-contact area of the non-mounting portion 422b that is not in contact with the support portion 37.

As shown in FIG. 11, the electronic device 20 includes a solder 70. The solder 70 joins each of the terminals 421 and 422 of the coil 42 to the corresponding land 35. The solder 70 is interposed between the mounting portion 421a of the terminal 421 and the land 351 to join the terminal 421 and the land 351 together. The solder 70 is interposed between the mounting portion 422a of the terminal 422 and the land 352 to join the terminal 422 and the land 352 together. The coupled inductor 40 is connected to the substrate 30, that is, mounted on the substrate 30 via the solders 70.

Due to the support structure using the support portion 37, the portions of the terminals 421 and 422, other than the portion supported by the support portion 37, are located at positions separated from the first surface 30a in the Z direction. Necessary gaps are provided between the mounting portions 421a and 422a of the terminals 421 and 422 and the corresponding lands 35 in order to ensure solder lifespan and connection reliability of the solders 70. The solders 70 each have a predetermined thickness necessary to ensure the solder lifespan and connection reliability.

In the connection structure between the substrate 30 and the coupled inductor 40 described above, current flows in the order of the wiring 341, the land 351, the terminal 421, the side wall 423, the upper wall 425, the side wall 424, the terminal 422, the land 352, and the wiring 342.

### Summary of First Embodiment

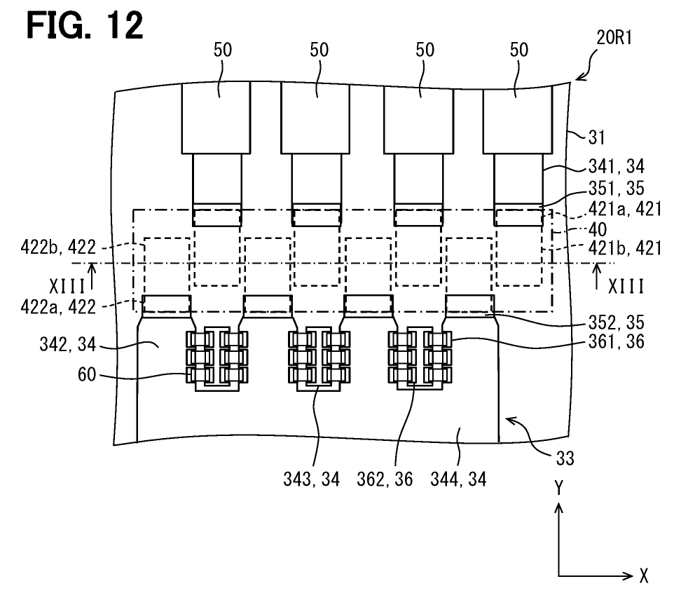

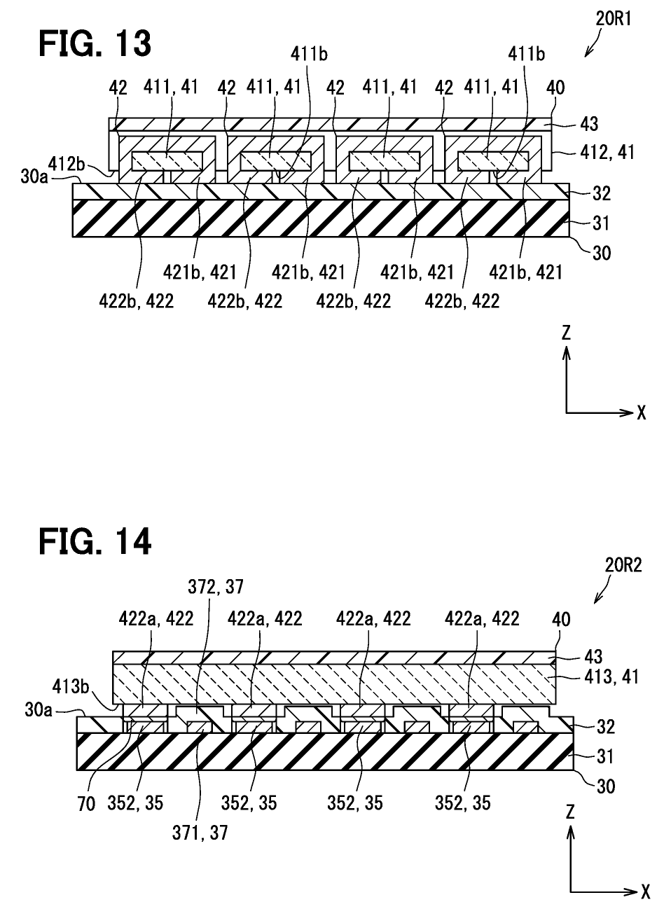

FIG. 12 shows a plan view of a reference example. FIG. 12 corresponds to FIG. 4. In FIG. 12, the coupled inductor is shown in a transparent manner. In FIG. 12, the resist is omitted. In FIG. 12, the outline of the coupled inductor is indicated by a one-dot chain line. Also, the terminals of the coupled inductor are indicated by dashed lines. FIG. 13 is a cross-sectional view taken along a line XIII-XIII in FIG. 12. FIG. 13 corresponds to FIG. 10.

The inductor component including the core 41 and the plurality of coils 42, such as the coupled inductor 40, as a single inductor component provides multiple inductors. Such an inductor component is heavier than an inductor component that provides only one inductor (i.e., a single inductor). Therefore, in a case of an electronic device 20R1 in which the substrate 30 does not have the support portion 37, as in the reference example shown in FIGS. 12 and 13, the coupled inductor 40 sinks during reflow of the solder 70 until the terminals 421 and 422 come into contact with the resist 32. The non-mounting portions 421b and 422b located directly below the core 41 come into contact with the resist 32, and the adjacent non-mounting portions 421b and 422b and the lower surfaces 411b, 412b and 413b of the core 41 form a space (restriction space) that restricts the movement of gas in the X direction. In this way, the non-mounting portions 421b and 422b hinder the ventilation. Therefore, condensation may occur due to the temperature difference between the area directly below the coupled inductor 40 and the outside, and there is a possibility that ion migration of Sn, which is a component of the solder 70, will occur.

In particular, in the case of the coupled inductor 40, it is necessary to strengthen the magnetic coupling in order to enhance the reduction effect of the effective inductance value, resulting in a structure in which the spaces between adjacent coils 42 and between adjacent terminals 421 and 422 are extremely narrow. As a result, the degree of sealing of the aforementioned regulated space increases. Furthermore, in a configuration where the coupled inductor 40 is provided with the cover 43, the upper part is also closed off by the cover 43, resulting in an even higher degree of sealing of the regulated space. Therefore, ion migration is more likely to occur.

FIG. 14 shows a cross-sectional view of another reference example. FIG. 14 corresponds to FIG. 11. In a case of an electronic device 20R2 as the reference example shown in FIG. 14, the support portion 37 is provided at a position that does not overlap with the terminals 421 and 422, and the terminals 421 and 422 are arranged on the substrate 30 side relative to the lower surface of the core 41. In other words, since the terminals 421 and 422 protrude toward the substrate 30 side, the coupled inductor 40 cannot be supported by the support portion 37. Therefore, as with the above-mentioned electronic device 20R1, the non-mounting portions 421b and 422b located directly below the core 41 hinder ventilation, and there is a risk of ion migration occurring.

The electronic device 20 of the present embodiment includes the substrate 30, the inductor component, and the solders 70. The inductor component includes the core 41 and the plurality of coils 42 that are arranged on the core 41 and aligned in a predetermined direction orthogonal to the thickness direction of the substrate 30. The plurality of coils 42 each have external connection terminals 421 and 422 that are disposed on the substrate 30 side relative to the surface of the core 41 facing the substrate 30. The terminals 421 and 422 has the mounting portions 421a and 422a, which are disposed so as to overlap with the corresponding lands 35 in the plan view from the thickness direction, and the non-mounting portions 421b and 422b, which are portions other than the mounting portions 421a and 422a and are arranged so as to overlap with the core 41 in the plan view. The substrate 30 includes the support portion 37 that is disposed so as to overlap with a portion of the non-mounting portion 421b or 422b of at least one of the terminals 421 and 422, and the support portion 37 protrudes toward the inductor component side relative to the land 35 and supports the inductor component via the non-mounting portion. In the illustrated electronic device 20, the coupled inductor 40 corresponds to the inductor component. The Z direction corresponds to the thickness direction, and the X direction corresponds to a predetermined direction.

By means of the support portion 37 provided on the substrate 30 so as to protrude toward the inductor component, the inductor component can be supported via the non-mounting portion 421b or 422b of the terminal 421 or 422. Since the support portion 37 is provided so as to overlap with a part of the non-mounting portion 421b or 422b, as illustrated in FIG. 10, a gap can be secured between the remaining portions of the non-mounting portions 421b and 422b not overlapping with the support portion 37 and the first surface 30a of the substrate 30. Therefore, ventilation will not be blocked, and consequently, the occurrence of ion migration can also be suppressed.

The configuration of the support portion 37 is not particularly limited. As illustrated, the support portion 37 may include the support conductor 371 disposed at a position separate from the land 35 on the one surface of the insulating base 31. Accordingly, since the support portion 37 can be formed by designing the substrate, the substrate 30 can be simplified. In addition, the manufacturing process can be simplified. For example, costs can be reduced.

As illustrated, the support portion 37 may include the resist 372 disposed so as to cover the support conductor 371. Since the support portion 37 including the resist 372 can be formed by designing the substrate, the configuration and manufacturing process of the substrate 30 can be further simplified.

The support conductor 371 may be electrically connected to the land 35. As illustrated, the support conductor 371 may be electrically isolated from all of the lands 35 that are joined to the coils 42. When the support conductor 371 is electrically connected to the land 35, the area of the land 35 is substantially increased by the support conductor 371, which may lead to deterioration of coil characteristics due to an increase in parasitic inductance and degradation in mountability due to uneven heating of the solder joint during the reflow. By electrically isolating the support conductor 371 from all of the lands 35, it is possible to suppress the aforementioned deterioration of coil characteristics and degradation in mountability. It should be noted that the support conductor 371, which is electrically isolated from the land 35, may be a dummy land that does not provide a wiring function, or a ground land that provides a ground potential.

As illustrated, the inductor component may include the cover 43 that is disposed on the surface of the core 41 opposite to the surface facing the substrate 30 and covers the core 41 and the plurality of coils 42. For example, the cover 43 can suppress adhesion of foreign matter. For example, the cover 43 can enhance the adhesiveness during reflow transport. Although the upper side of the inductor component is closed due to the cover 43, it is possible to suppress the occurrence of ion migration.

### Modified Example

Although the example in which the support portion 37 (support conductor 371) is disposed so as to overlap with the non-mounting portion 422b that is closest to the center of the longitudinal direction (X direction) of the coupled inductor 40 has been shown, the present disclosure is not limited to such an example. The support portion 37 may also be disposed so as to overlap with the non-mounting portion 421b closest to the center in the longitudinal direction of the coupled inductor 40. In either configuration, it is possible to stably support the coupled inductor 40 by supporting the single non-mounting portion with the single support portion 37.

Although the example in which the support portion 37 includes the resist 372 has been shown, the present disclosure is not limited to such an example. For example, the support portion 37 may be composed of a support conductor 371 exposed from the resist 32 and a metal piece joined to the support conductor 371. In order not to affect the circuit operation of the coupled inductor 40, the support conductor 371 may be, for example, a dummy land that does not provide wiring function, or a ground land that provides a ground potential.

Although the coupled inductor 40 has been described as an example of the inductor component, the inductor component is not limited to such an example. The inductor component is not limited to a configuration in which the plurality of coils 42 are arranged on a common core 41 and the plurality of coils 42 are magnetically coupled. The core 41 may be provided individually for each coil 42. The inductor component may, for example, be packaged in such a manner that the plurality of coils 42 are arranged along a predetermined direction.

Although an example in which one support portion 37 supports one of the terminals 421 and 422 has been shown, the present disclosure is not limited to such an example. One support portion 37 may support at least one of the terminals 421 and 422. For example, one support portion 37 may support one or more terminals 421 and 422.

### (Second Embodiment)

A second embodiment is a modified example of the preceding embodiment as a basic configuration and may incorporate description of the preceding embodiment. In the preceding embodiment, one terminal (non-mounting portion) is supported by one support portion. Alternatively, a plurality of terminals may be supported by a plurality of support portions.

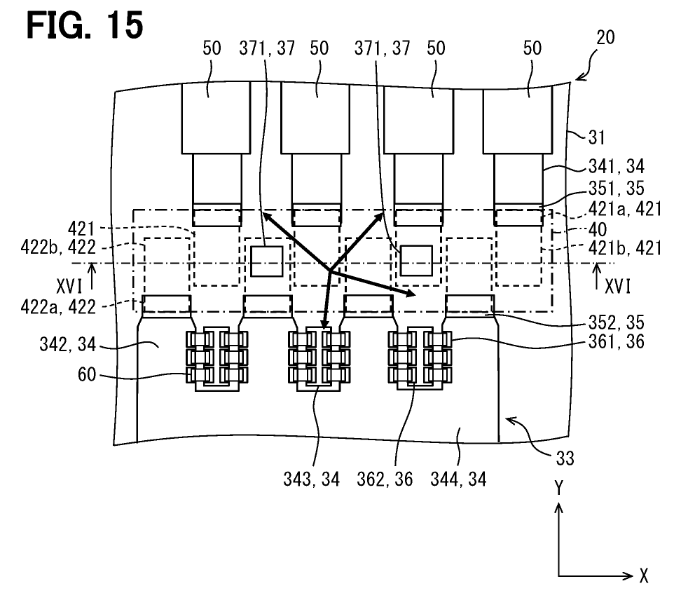

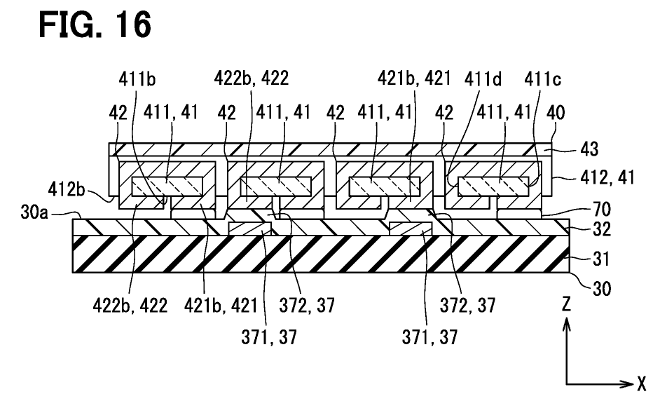

FIG. 15 shows a plan view of an electronic device according to the present embodiment. FIG. 15 corresponds to FIG. 4. In FIG. 15, the coupled inductor is shown in a transparent manner. In FIG. 15, the resist is omitted. In FIG. 15, the outline of the coupled inductor is indicated by a one-dot chain line. Additionally, the terminals of the coupled inductor are indicated by broken lines. In FIG. 15, gas escaping paths between the support portions are indicated by solid arrows. FIG. 16 is a cross-sectional view taken along a line XVI-XVI in FIG. 15.

In the electronic device 20 shown in FIG. 15, the substrate 30 has a plurality of the support portions 37. In other words, the electronic device 20 has a configuration in which one coupled inductor 40 is supported by the plurality of support portions 37. The plurality of support portions 37 are arranged in the X direction, which is the arrangement direction of the coils 42. In the illustrated electronic device 20, the plurality of support portions 37 are spaced apart in the X direction so that the terminals 421 and 422 that do not overlap with the support portions 37 are positioned between the adjacent support portions 37.

In FIGS. 15 and 16, the substrate 30 has two support portions 37. One of the support portions 37 supports the non-mounting portion 421b of the terminal 421 of the second coil 42 from one end of the coupled inductor 40 in the X direction. The other support portion 37 supports the non-mounting portion 422b of the terminal 422 of the third coil 42 from the one end in the X direction. Between the two support portions 37, the terminal 422 of the second coil 42 and the terminal 421 of the third coil 42 are positioned. One of the support portions 37 is positioned on one side relative to the center of the coupled inductor 40, and the other support portion 37 is positioned on the other side relative to the center in the longitudinal direction of the coupled inductor 40. The other configurations of the second embodiment are similar to those described in the preceding embodiment.

### Summary of Second Embodiment

As illustrated, the substrate 30 may have the plurality of support portions 37 disposed to support one single inductor component. In the illustrated electronic device 20, the coupled inductor 40 corresponds to the inductor component. Since the inductor component is supported by the plurality of support portions 37 arranged along the arrangement direction of the coil 42, it is possible to suppress the inductor component from tilting. In other words, the inductor component can be supported more stably. By suppressing the tilting, it is possible to suppress the space between the inductor component and the substrate 30 from becoming partially narrower, thereby suppressing the decrease in ventilation.

As illustrated, in the configuration where the plurality of support portions 37 are arranged in the predetermined direction, the adjacent support portions 37 may be spaced apart in the predetermined direction so that the terminals 421 and 422 that do not overlap with the support portions 37 are positioned between the adjacent support portions 37. In such a configuration, tilting of the inductor component can be suppressed more effectively. In addition, since the space between the support portions 37 is widened, it is possible to secure a greater number of gas escaping paths from this space, as illustrated by the solid arrows in FIG. 15. Therefore, even if the electronic device 20 has the plurality of support portions 37, it is less likely that the plurality of support portions 37 obstruct ventilation.

### Modified Example

The configuration described in the second embodiment can be combined with the configurations described in the preceding embodiment(s) or the modified example(s) thereof.

The arrangement of the plurality of support portions 37 is not limited to the examples described above. The support portion 37 may be provided directly below each of the adjacent terminals 421 and 422. In consideration of the ventilation, it is preferable to arrange the support portions 37 so that at least one terminal is positioned between the adjacent support portions 37.

The number of support portions 37 is not limited to two. The substrate 30 may be provided with three or more support portions 37.

### (Third Embodiment)

A third embodiment is a modified example of the preceding embodiment(s) as a basic configuration and may incorporate description(s) of the preceding embodiment(s). In the preceding embodiment(s), the plurality of terminals are supported by the plurality of support portions. In addition to this, it is also possible to suppress the influence of substrate distortion acting on the solder.

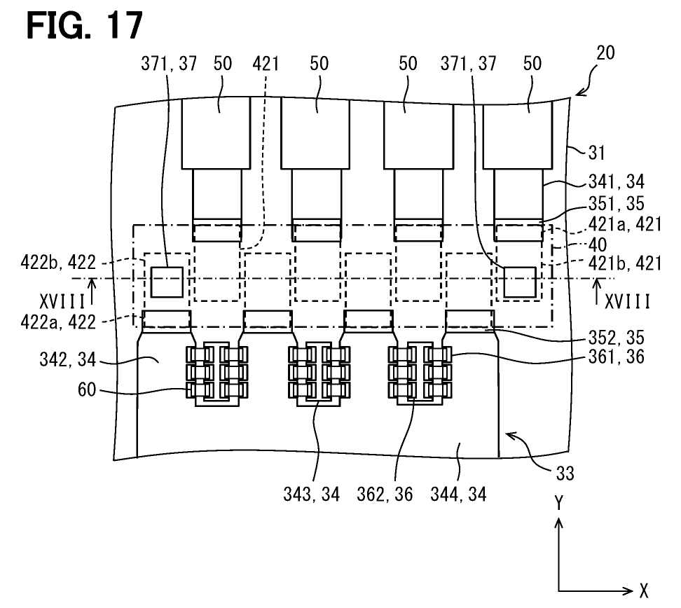

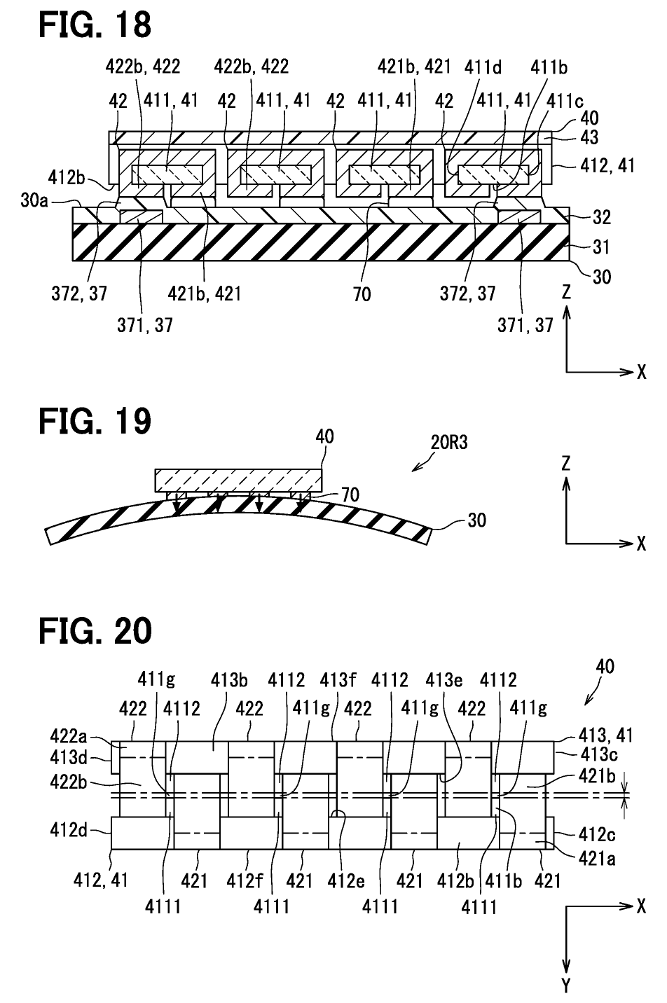

FIG. 17 shows a plan view of an electronic device according to the present embodiment. FIG. 17 corresponds to FIG. 4. In FIG. 17, the coupled inductor is shown in a transparent manner. In FIG. 17, the resist is omitted. In FIG. 17, the outline of the coupled inductor is indicated by a one-dot chain line. Also, the terminals of the coupled inductor are indicated by dashed lines. FIG. 18 is a cross-sectional view taken along a line XVIII-XVIII in FIG. 17.

The substrate 30 of the electronic device 20 shown in FIG. 17 also has the plurality of support portions 37. The plurality of support portions 37 are arranged in the X direction, which is the arrangement direction of the coils 42. The illustrated substrate 30 has two support portions 37. The two support portions 37 are provided directly below the terminals 421 and 422 located at both ends. One of the support portions 37 is disposed so as to overlap with a part of the non-mounting portion 421b of the terminal 421, which is located at the end adjacent to the side surfaces 412c and 413c. The other support portion 37 is disposed so as to overlap with a part of the non-mounting portion 421b of the terminal 422, which is located at the opposite end adjacent to the side surfaces 412d and 413d. The other configurations of the third embodiment are similar to those described in the preceding embodiment(s).

### Summary of Third Embodiment

FIG. 19 is a diagram showing the influence of substrate distortion in a reference example. In an electronic device 20R3 shown in FIG. 19, the substrate 30 does not have the support portion 37. Similar to the electronic device 20, the coupled inductor 40 has four coils 42 (not shown) arranged in the X direction. As the number of coils 42 increases, the coupled inductor 40 becomes longer in the X direction. For example, when substrate distortion (warpage) occurs such that the ends of the substrate move away from the vicinity of the substrate center in the ZX plane, stress due to the substrate distortion acts on the solders 70. The stress acting on the solders 70 is greater at the ends of the coupled inductor 40. That is, the stress acting on the solders 70 increases toward the end coils 42 at both ends, among the plurality of coils 42. Therefore, the connection reliability of the solders 70 near both ends decreases.

In the present embodiment, the support portions 37 are disposed directly below the coils 42 located at both ends in the predetermined direction. The predetermined direction corresponds to the X direction. In this way, by arranging the support portions 37 at both ends to support the end positions at which the influence of substrate distortion is likely to be large, it is possible to alleviate the stress acting on the solders 70 that join the terminals 421 and 422 at both ends to the corresponding lands 35. Therefore, in addition to the effects described in the preceding embodiment(s), it is possible to further improve solder lifespan and connection reliability.

### Modified Example

The configuration described in the present embodiment can be combined with the configuration(s) described in the first embodiment and its modified example(s), or with the configuration(s) described in the second embodiment and its modified example(s).

The arrangement of the plurality of support portions 37 is not limited to the positions directly below the end coils. For example, as shown in FIGS. 15 and 16, the plurality of support portions 37 may be provided directly below the coils 42, which are disposed at positions closer to the end portions of the inductor component than the center of the inductor component in the predetermined direction (X direction). As described above, the stress acting on the solders 70 increases as closer to both ends of the plurality of coils 42. Therefore, by providing the support portions 37 directly below the coils 42 at positions closer to the end portions than the center, it is possible to alleviate the stress acting on the solders 70.

### (Fourth Embodiment)

A fourth embodiment is a modified example of the preceding embodiment(s) as a basic configuration and may incorporate description(s) of the preceding embodiment(s). In the preceding embodiment(s), the core portion is not divided. Alternatively, the core portion may be divided into a plurality of sections.

FIG. 20 shows a plan view of the coupled inductor as seen from the lower surface side in an electronic device according to the present embodiment. FIG. 20 corresponds to FIG. 7. In FIG. 20, the cover 43 is omitted for convenience. In the coupled inductor 40 of the present embodiment, the core portion 411 of the core 41 is divided into a plurality of sections. In the direction in which the end portions 412 and 413 face each other (Y direction), the core portion 411 is divided into a plurality of sections. In the illustrated example, the core portion 411 is divided at the central position in the Y direction. The core portion 411 includes a core portion 4111 and a core portion 4112.

The core portion 4111 is connected to the end portion 412. The core portion 4111 extends from the side surface 412e of the end portion 412 toward the opposite end portion 413. The core portion 4112 is connected to the end portion 413. The core portion 4112 extends from the side surface 413e of the end portion 413 toward the opposite end portion 412. The core 41 has a gap 411g in which no magnetic material is disposed, between the facing surfaces of the core portions 4111 and 4112. For example, an adhesive is disposed in the gap 411g, so that the core portions 4111 and 4112 are fixed to each other. In FIG. 20, a width between one-dot chain lines indicates the width of the gap 411g.

It should be noted that the dividing position is not limited to the center. It is also possible to adopt a configuration in which a single core portion 411 is continuous from one of the end portions 412 or 413, and is bonded to the other end portion by adhesive. Both ends of the single core portion 411 may also be bonded to each of the end portions 412 and 413. The core portion 411 may be divided into three or more sections.

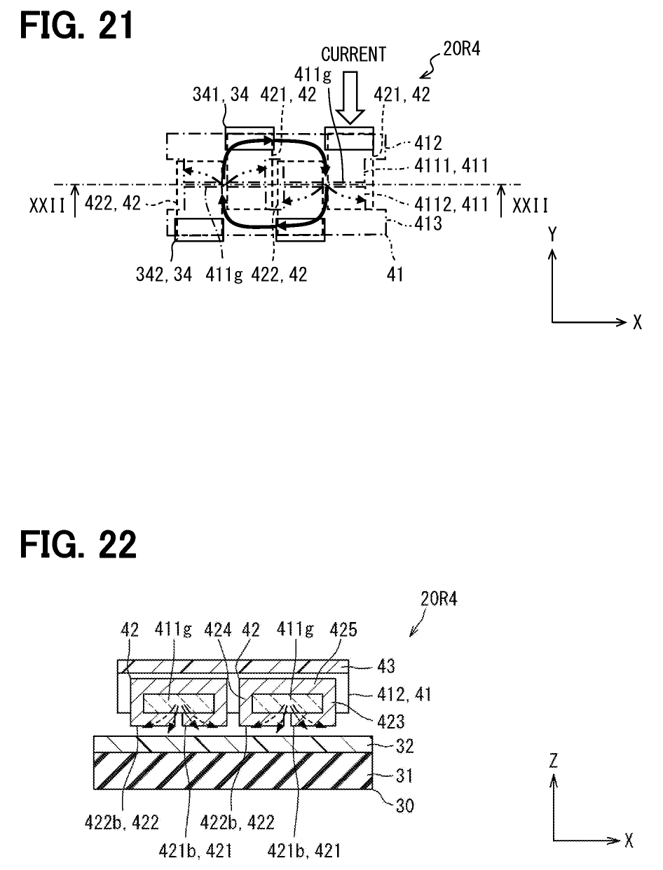

FIG. 21 shows a reference example in which the core portion 411 of the core 41 is divided, and the support portion 37 is not provided. FIG. 21 shows the example in which the coupled inductor 40 has two core portions 411, that is, two coils 42. In FIG. 21, of the substrate 30, only the land 35 is shown. Furthermore, of the coupled inductor 40, only the core 41 and the terminals 421 and 422 of the coil 42 are shown. FIG. 22 is a cross-sectional view taken along a line XXII-XXII in FIG. 21. In FIGS. 21 and 22, arrows with two-dot chain lines indicate leakage magnetic fluxes.

In FIG. 21, in an electronic device 20R4 of the reference example, a magnetic flux path when current flows from the land 351 to the land 352 through one of the coils 42 is indicated by solid arrows. The two core portions 411 are connected to the end portions 412 and 413. When the current flows through one of the coils 42, a loop-shaped magnetic flux path is formed via the core portion 411 around which the other coil 42 is wound. At this time, because a gap 411g is present, magnetic flux leaks from the gap 411g, as shown in FIGS. 21 and 22. The coil 42 is wound around the core portion 411. However, there is no coil 42 (conductor) present in the region between the terminal 421 and the terminal 422. Therefore, the magnetic flux is likely to leak particularly from a portion where the gap 411g overlaps with the region between the terminal 421 and the terminal 422. Due to the leakage magnetic flux, emissions deteriorate.

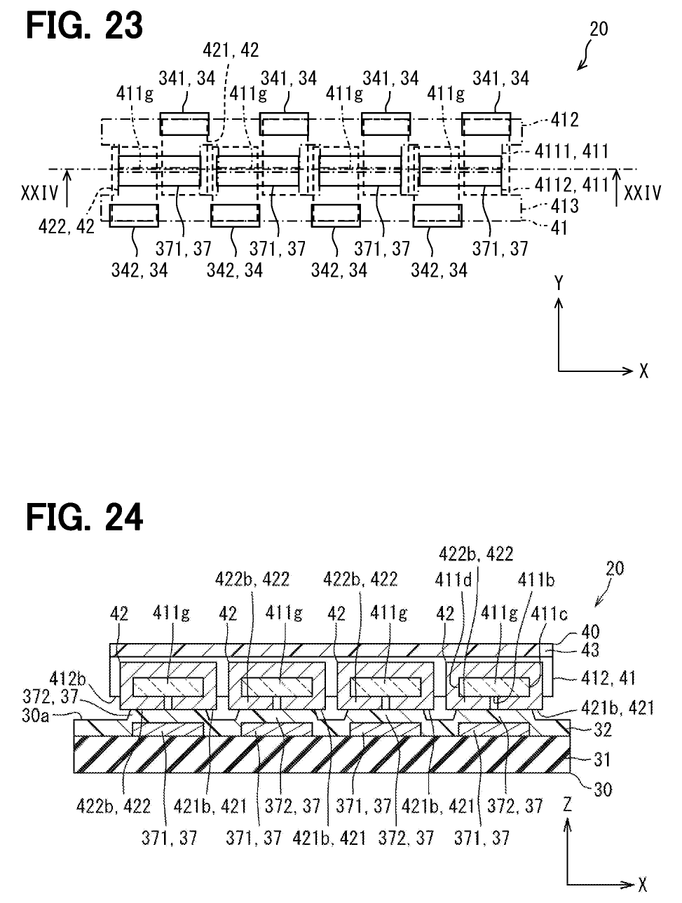

FIG. 23 is a diagram showing the arrangement of the gap of the core, the terminals of the coil, and the support portion in the electronic device according to the present embodiment. In FIG. 23, of the substrate 30, only the land 35 is shown. Additionally, of the coupled inductor 40, only the core 41 and the terminals 421 and 422 of the coil 42 are shown. FIG. 24 is a cross-sectional view of the electronic device taken along a line XXIV-XXIV in FIG. 23.

Similar to the preceding embodiment(s), the electronic device 20 has the support portion 37 including the support conductor 371. The support portion 37 is disposed so as to overlap with at least one of the plurality of core portions 411 in the plan view. The support portion 37 is disposed so as to overlap with at least a part of the gap 411g in one of the core portions 411.

In the illustrated electronic device 20, the substrate 30 has four support conductors 371 (support portions 37). The support portion 37 includes the support conductor 371 and the resist 372. The support portion 37 is provided individually for each coil 42. The support portion 37 is provided individually for each core portion 411. In each of the support portions 37, the support conductors 371 are disposed in a part where the gaps 411g of the corresponding core portion 411 and the region between terminal 421 and the terminal 422 of the corresponding coil 42 overlap with each other. The support conductor 371 is disposed so as to overlap with the entire gap 411g of the corresponding core portion 411. The support conductor 371 is disposed so as to overlap with the entire gap 411g in all of the core portions 411. Since the support conductor 371 is present directly below the gap 411g, it is possible to suppress magnetic flux leakage from the gap 411g. The other configurations of the present embodiment are similar to those of the preceding embodiment(s).

### Summary of Fourth Embodiment

As illustrated, in the core 41 of the coupled inductor 40, the core portion 411 may be divided into multiple sections to have the gap 411g therebetween. The support portion 37 may be arranged so as to overlap with at least a part of the gap 411g in the plan view. In such a configuration, the support portion 37 disposed facing the gap 411g can suppress leakage of the magnetic flux from the gap 411g. By providing the support portion 37, the leakage of the magnetic flux can be suppressed, as compared to a configuration without having the support portion 37, that is, a configuration in which air is present. In particular, the support conductor 371 arranged so as to face the gap 411g can enhance this effect.

As illustrated, the support portion 37 may be disposed in a part of the gap 411g that overlaps with the region between a first terminal and a second terminal of the coil 42 in the plan view. In the illustrated electronic device 20, one of the terminals 421 and 422 corresponds to the first terminal, and the other of terminals 421 and 422 corresponds to the second terminal. The conductor forming the coil 42 is wound around the core portion 411. However, the first terminal and the second terminal are arranged with a predetermined spacing therebetween. Therefore, magnetic flux is more likely to leak from the part of the gap 411g that overlaps with the region between the first terminal and the second terminal. By arranging the support portion 37 at the part of the gap 411g that overlaps with the region between the first terminal and the second terminal, leakage of magnetic flux can be effectively suppressed.

As illustrated, the support portion 37 may be arranged so as to overlap with the entire gap 411g in a single core portion 411. Since the support portion 37 is arranged so as to face the entire region of the gap 411g, leakage of magnetic flux can be suppressed more reliably.

As illustrated, the support portion 37 may be arranged so as to overlap with at least a part of each of the gaps 411g provided in the plurality of core portions 411. Since the support portion 37 is arranged to face all of the plurality of gaps 411g, leakage of the magnetic flux can be suppressed in the entire coupled inductor 40.

### Modified Example

The configuration described in the present embodiment can be combined with any of the configuration described in the first embodiment and its modified example, the configuration described in the second embodiment and its modified example, and the configuration described in the third embodiment and its modified example.

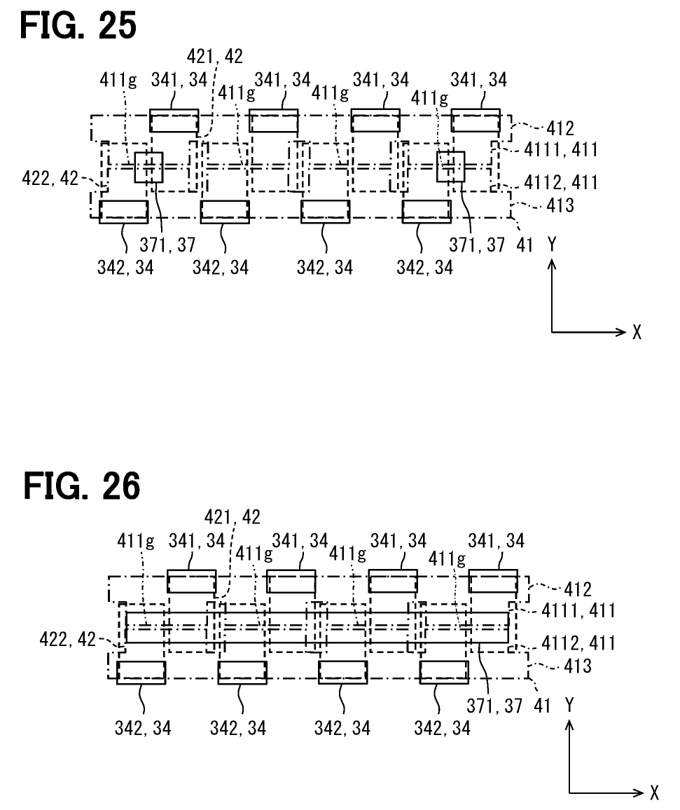

The arrangement of the support portion 37 (support conductor 371) is not limited to the examples described above. The support portion 37 may be provided for only one of the plurality of core portions 411. As shown in FIG. 25, the support portion 37 may be provided for two of the four core portions 411. Although not shown in the drawings, the support portion 37 may be provided for three of the four core portions 411.

The support portion 37 may be disposed so as to overlap at least a part of the gap 411g in the plan view. The support portion 37 may be disposed in a part of the gap 411g that does not overlap with the region between the first terminal and the second terminal. As shown in FIG. 25, the support portion 37 may be disposed so as to face a part of the gap 411g including a portion overlapping with the region between the first terminal and the second terminal in the gap 411g.

Although an example in which one support portion 37 (support conductor 371) is provided for one core portion 411 has been shown, the present disclosure is not limited to such an example. For example, as shown in FIG. 26, one support portion 37 may be provided for four core portions 411. In FIG. 26, a single support portion 37 (support conductor 371) is arranged so as to overlap all of the gaps 411g of the four core portions 411. The support conductor 371 has a substantially rectangular planar shape with its longitudinal direction along the X direction, which is the arrangement direction of the coils 42, similar to the coupled inductor 40.

### (Fifth Embodiment)

A fifth embodiment is a modified example of the preceding embodiment(s) as a basic configuration and may incorporate description(s) of the preceding embodiment(s). In the preceding embodiment(s), a support conductor is provided separately from the wiring that electrically connects the capacitor and the switching device. Alternatively, the support conductor may be provided as a part of the wiring that electrically connects the capacitor and the switching device.

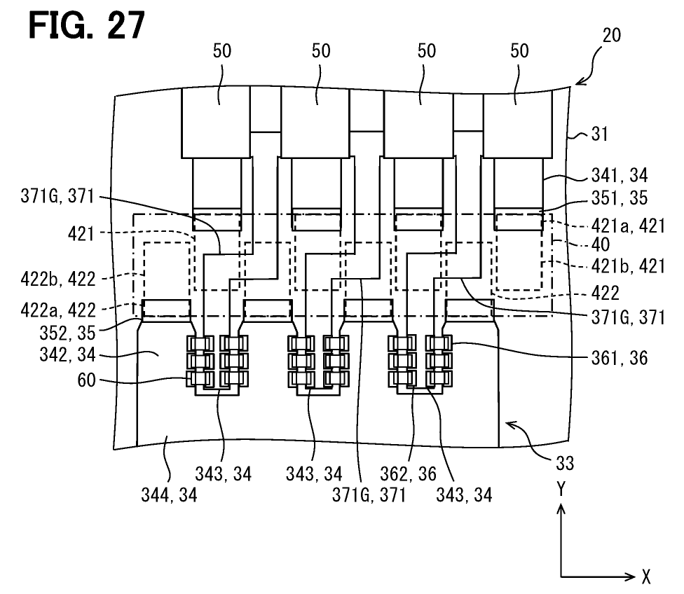

FIG. 27 is a plan view showing an electronic device according to the present embodiment. FIG. 27 corresponds to FIG. 4. In FIG. 27, the coupled inductor is shown in a transparent manner. In FIG. 27, the resist is omitted. In FIG. 27, the outline of the coupled inductor is indicated by a one-dot chain line. Further, the terminals of the coupled inductor are indicated by dashed lines.

The substrate 30 includes a wiring 343 that is disposed in the surface layer of the insulating base 31 adjacent to the first surface 30a. The wiring 343 extends generally in the Y direction. The wiring 343 electrically connects the ground terminal of the capacitor 60 and a ground terminal (not shown) of the switching device 50. The wiring 343 is a ground wiring. The wiring 343 crosses the coupled inductor 40 in the Y direction. In the plan view, the wiring 343 is disposed so as to overlap with at least one of the non-mounting portions 421b and 422b of the terminals 421 and 422. Of the wiring 343, the portions that overlap with the non-mounting portions 421b and 422b of the terminals 421 and 422 functions as a support conductor 371. The support portion 37 includes the support conductor 371 and the resist 372, for example. The capacitor 60 is connected near one end of the wiring 343, and the switching device 50 is connected near the other end.

The illustrated substrate 30 has three wirings 343. All the three wirings 343 cross the coupled inductor 40. The support conductor 371, which forms part of the wiring 343, is arranged so as to overlap with the two terminals 421 and 422 that are positioned adjacent to each other in the plan view. The substrate 30 has three support conductors 371 (support portions 37). One of the support conductors 371 includes a portion extending in the X direction so as to overlap with one non-mounting portion 421b of the terminal 421 and one non-mounting portion 422b of the terminal 422. The other configurations of the present embodiment are similar to those of the preceding embodiment(s).

### Summary of Fifth Embodiment

As illustrated, the inductor component may be disposed between the switching device 50 and the capacitor 60 in a direction orthogonal to both the thickness direction of the substrate and the predetermined direction. In this arrangement, the ground wiring that electrically connects the capacitor 60 and the switching device 50 may be used as the support conductor 371. In the illustrated electronic device 20, the Z direction corresponds to the thickness direction, and the X direction corresponds to the predetermined direction. The Y direction corresponds to the orthogonal direction or a facing direction of the end portions 412 and 413. The coupled inductor 40 corresponds to the inductor component, and the wiring 343 corresponds to the ground wiring.

As described above, the ground wiring is disposed directly below the inductor component, and a part of the ground wiring is used as the support conductor 371. As a result, the return path from the capacitor 60 to the switching device 50 can be shortened, thereby reducing emissions. Therefore, it is possible to reduce emissions while suppressing ion migration. In particular, in the configuration shown in FIG. 27, the capacitor 60 and the switching device 50 are electrically connected only by the wiring 343 arranged in the surface layer on the first surface 30a side. Therefore, the return path can be further shortened, and emissions can be effectively reduced.

### Modified Example

The configuration in which the part of the ground wiring electrically connecting the capacitor 60 and the switching device 50 serves as the support conductor 371 is not limited to the example described above. As the part of the ground wiring electrically connecting the capacitor 60 and the switching device 50, an inner layer wiring disposed inside the insulating base 31 may be included. The inner layer wiring is connected to the surface layer wiring through a via conductor. Of the ground wirings electrically connecting the capacitor 60 and the switching device 50, for example, only the island-shaped wiring 343 and the support conductor 371 illustrated in FIG. 4 may be provided as surface layer wirings, and the other portions may be provided as inner layer wirings.

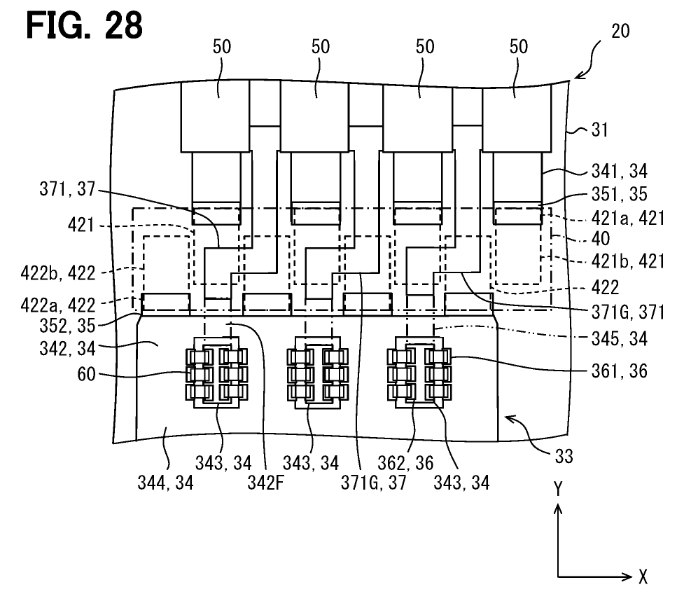

As shown in FIG. 28, the wiring 342 may have a connecting portion 342F that connects a plurality of wirings 342 between the land 352 and the land 361. By connecting the wirings 342 between phases via the connecting portion 342F, the capacitor 60 can be utilized across phases. As a result, it is possible to reduce the number of capacitors 60 while arranging the capacitor 60 in the vicinity of the coupled inductor 40. In FIG. 28, in order to avoid the connecting portion 342F, a part of the wiring 343 shown in FIG. 27 is replaced with a wiring 345 arranged in the inner layer. As a result, the turn path can be shortened, and emissions can be reduced.

### (Other Embodiments)

The present disclosure in this specification and the drawings is not limited to the illustrated embodiments. The present disclosure encompasses the illustrated embodiments as well as modifications thereof made by those skilled in the art based on these embodiments. For example, the present disclosure is not limited to the combinations of components and/or elements shown in the embodiments. The present disclosure can be implemented in various combinations. The present disclosure may include additional parts that can be added to the embodiments. The present disclosure encompasses embodiments in which components and/or elements of the embodiments are omitted. The present disclosure encompasses the replacement or combination of components and/or elements between one embodiment and another embodiment. The technical scope of the present disclosure is not limited to the descriptions of the embodiments. It should be understood that the present disclosure further includes modifications within an equivalent scope of the present disclosure.

Various modifications to the described embodiments will be apparent to those skilled in the art.

When an element or a layer is described as “disposed above” or “connected to”, the element or the layer may be directly disposed above or connected to another element or another layer, or an intervening element or an intervening layer may be present. In contrast, when an element is described as “directly disposed on,” “directly coupled to,” “directly connected to”, or “directly combined with” another element or another layer, there are no intervening elements or layers present. Other terms used to describe the relationships between elements (for example, “between” vs. “directly between”, and “adjacent” vs. “directly adjacent”) should be interpreted similarly. As used herein, the term “and/or” includes any combination and all combinations relating to one or more of the related listed items. For example, the term A and/or B includes only A, only B, or both A and B. The phrase of A and/or B means at least one of A or B.

Spatial relative terms “inside”, “outside”, “back”, “bottom”, “low”, “top”, “high”, and the like are used herein to facilitate the description that describes relationships between one element or feature and another element or feature. Spatial relative terms can be intended to include different orientations of a device in use or operation, in addition to the orientations illustrated in the drawings. For example, when a device in a drawing is turned over, elements described as “below” or “directly below” other elements or features are oriented “above” the other elements or features. Therefore, the term “below” can include both above and below. The device may be oriented in the other direction (rotated 90 degrees or in any other direction) and the spatially relative terms used herein are interpreted accordingly.

What is claimed is:

1. An electronic device comprising:
a substrate including an insulating base and a plurality of lands disposed on one surface of the insulating base;
an inductor component including a core and a plurality of coils that are disposed on the core and arranged in a predetermined direction orthogonal to a thickness direction of the substrate; and
a plurality of solders joining the plurality of coils and the plurality of lands, wherein
each of the plurality of coils has an external connection terminal disposed adjacent to the substrate relative to a surface of the core facing the substrate,
the external connection terminal includes a mounting portion disposed so as to overlap with a corresponding land in a plan view from the thickness direction, and a non-mounting portion that is a portion other than mounting portion and disposed so as to overlap with the core in the plan view,
the substrate includes a support portion that is disposed so as to overlap with a part of the non-mounting portion of at least one of the external connection terminals in the plan view, and
the support portion protrudes toward the inductor component relative to the corresponding land, and supports the inductor component through the non-mounting portion of the at least one of the external connection terminals.

2. The electronic device according to claim 1, wherein
the support portion includes a support conductor disposed at a position separated from the plurality of lands on the one surface of the insulating base.

3. The electronic device according to claim 2, wherein
the support portion includes a resist disposed so as to cover the support conductor.

4. The electronic device according to claim 3, wherein
the support conductor is electrically isolated from all of the lands joined to the coils.

5. The electronic device according to claim 1, wherein
the substrate includes a plurality of the support portions provided to support the inductor component as a single component.

6. The electronic device according to claim 5, wherein
the plurality of support portions are arranged in the predetermined direction, and
adjacent support portions are spaced apart from each other in the predetermined direction such that at least one of the external connection terminals that does not overlap with the support portions is positioned between the adjacent support portions.

7. The electronic device according to claim 5, wherein
at least one of the plurality of support portions is disposed directly below at least one of the coils, the at least one of the coils being located closer to an end of the inductor component than a center of the inductor component in the predetermined direction.

8. The electronic device according to claim 7, wherein
at least one of the plurality of support portions is disposed directly below at least one of the coils that are located at both ends of the inductor component in the predetermined direction.

9. The electronic device according to claim 1, wherein
the core includes:
a plurality of core portions that are correspondingly and individually provided for the plurality of coils and on which the plurality of coils are wound; and
a first end portion and a second end portion facing each other in a facing direction that is orthogonal to the predetermined direction and the thickness direction, the plurality of core portions are disposed between the first end portion and the second end portion so that first ends of the plurality of core portions are connected to the first end portion and second ends of the plurality of core portions are connected to the second end portion,
each of the plurality of core portions is divided in the facing direction to have a gap in the facing direction, and
the support portion is disposed so as to overlap with at least a part of the gap in the plan view.

10. The electronic device according to claim 9, wherein
each of the plurality of coils has, as the external connection terminals, a first terminal and a second terminal spaced from the first terminal in the predetermined direction across a predetermined interval, and
the support portion is disposed so as to overlap with a region between the first terminal and the second terminal in the gap in the plan view.

11. The electronic device according to claim 10, wherein
the support portion is disposed so as to overlap with the entire gap of one of the core portions.

12. The electronic device according to claim 9, wherein
the support portion is disposed so as to overlap with at least a part of each of the gaps provided in the plurality of cores.

13. The electronic device according to claim 2, further comprising:
a switching device and a capacitor that are disposed on the substrate to constitute a multi-phase power supply together with the inductor component, wherein
the inductor component is disposed between the switching device and the capacitor in a direction that is orthogonal to both the thickness direction and the predetermined direction, and
the support conductor is a ground wiring that electrically connects the capacitor and the switching device.

14. The electronic device according to claim 1, wherein
the inductor component includes a cover that is disposed on a surface of the core on an opposite side to the substrate so as to cover the core and the plurality of coils.
